(19) United States
(12) Patent Application Publication
(10) Pub. No.: US 2019/0157098 A1
(43) Pub. Date: May 23, 2019

(54) Etching Method and Method of Filling Recessed Pattern Using the Same

(71) Applicant: TOKYO ELECTRON LIMITED, Tokyo (JP)

(72) Inventors: Takahito UMEHARA, Iwate (JP); Hiroki MIURA, Iwate (JP)

(21) Appl. No.: 16/191,818

(22) Filed: Nov. 15, 2018

(30) Foreign Application Priority Data
Nov. 20, 2017 (JP) 2017-222834

(51) Int. Cl. H01L 21/311; C23C 16/40; C23C 16/455; C23C 16/56; H01L 21/02

(52) U.S. Cl. CPC H01L 21/31116; C23C 16/402; H01L 21/02164; C23C 16/56; C23C 16/45525

(57) ABSTRACT

An etching method for etching a film in a recessed pattern formed on a surface of a substrate in a process chamber to form a V-shaped sectional shape includes setting two or more parameters of the process chamber to such conditions that an etching rate of the surface of the substrate becomes higher than that of an inside of the recessed pattern; and supplying an etching gas to the surface of the substrate under the condition.

### CROSS-REFERENCE TO RELATED APPLICATION

This application is based upon and claims the benefit of priority from Japanese Patent Application No. 2017-222834, filed on Nov. 20, 2017, the entire contents of which are incorporated herein by reference.

### TECHNICAL FIELD

The present disclosure relates to an etching method and a method of filling a recessed pattern using the same.

### BACKGROUND

Conventionally, a substrate processing method is known to include an etching process of loading a substrate on a rotary table installed in a process chamber and etching a film formed on a surface of the substrate by supplying an etching gas into the process chamber while rotating the rotary table. In the substrate processing method, the process chamber is divided into a processing region to which the etching gas is supplied along the rotation direction of the rotary table and a purge region to which a purge gas is supplied while the etching gas is not being supplied so that the substrate passes through the process region and the purge region one time when the rotary table is rotated once, and an etching rate at which the film is etched or a surface roughness of the film after etching is controlled by changing the rotation speed of the rotary table.

In such a substrate processing method, a desired film quality is obtained by controlling the etching rate or the surface roughness of the film after etching using the principle in which change in gas concentration on the surface of the rotary table occurs when changing the rotation speed.

However, changing the rotation speed of the rotary table can only control the concentration of the etching gas on the surface of the substrate. It cannot control an etching rate in the depth direction of a recessed pattern.

### SUMMARY

Some embodiments of the present disclosure provide an etching method capable of controlling an etching amount in a depth direction of a recessed pattern formed on a surface of a substrate, and a method of filling a recessed pattern using the same.

According to one embodiment of the present disclosure, there is provided an etching method for etching a film in a recessed pattern formed on a surface of a substrate in a process chamber to form a V-shaped sectional shape including setting two or more parameters of the process chamber to such conditions that an etching rate of the surface of the substrate becomes higher than that of an inside of the recessed pattern; and supplying an etching gas to the surface of the substrate under the condition.

According to one embodiment of the present disclosure, there is provided a method of filling a recessed pattern, including: forming a conformal film that conforms to a shape of the recessed pattern in the recessed pattern formed on a surface of a substrate in a process chamber; etching the conformal film to form a V-shaped sectional shape by performing the above-described etching method in the process chamber; and forming a conformal film that conforms to the V-shaped sectional shape on the conformal film having the V-shaped sectional shape in the process chamber.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view of an example of a substrate processing apparatus capable of performing an etching method and a method of filling a recessed pattern according to an embodiment of the present disclosure.

FIG. 2 is a perspective view of an example of the substrate processing apparatus capable of performing an etching method and a method of filling a recessed pattern according to an embodiment of the present disclosure.

FIG. 3 is a schematic top view of an example of the substrate processing apparatus capable of performing an etching method and a method of filling a recessed pattern according to an embodiment of the present disclosure.

FIGS. 4A and 4B are configuration diagrams of a gas nozzle and a nozzle cover of the substrate processing apparatus capable of performing an etching method and a method of filling a recessed pattern according to an embodiment of the present disclosure.

FIG. 5 is a partial cross-sectional view of an example of the substrate processing apparatus capable of performing an etching method and a method of filling a recessed pattern according to an embodiment of the present disclosure.

FIG. 6 is another partial cross-sectional view of an example of the substrate processing apparatus capable of performing an etching method and a method of filling a recessed pattern according to an embodiment of the present disclosure.

FIGS. 7A to 7D are views illustrating a series of processes of a method of filling a recessed pattern including an etching method according to an embodiment of the present disclosure.

FIG. 8 is a view illustrating an example of a conventional film forming method in which a void is generated.

FIGS. 9A and 9B are tables illustrating etching conditions performed to find the validity of parameters and effective set values related to the etching method according to the present embodiment.

FIG. 10 is a table illustrating SEM images and measured values after etching for level Nos. 1 to 6 in FIGS. 9A and 9B.

FIG. 11 is a graph illustrating evaluation results illustrated in FIG. 10.

FIG. 12 is a view illustrating a shape of a trench T of a sample used in the present example.

FIG. 13 is a diagram illustrating results of implementation of the present example.

FIG. 14 is a diagram illustrating results of implementation according to a comparative example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, modes for carrying out the present disclosure will be described with reference to the drawings.

### [Substrate Processing Apparatus]

First, a substrate processing apparatus capable of suitably implementing an etching method and a method of filling a recessed pattern according to an embodiment of the present disclosure will be described.

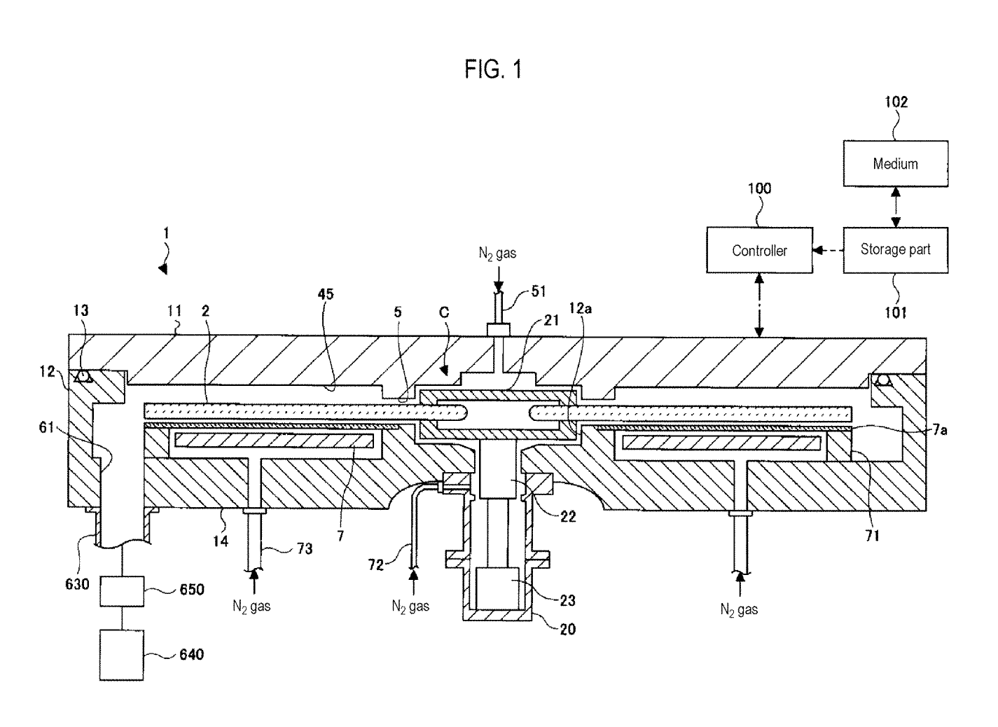

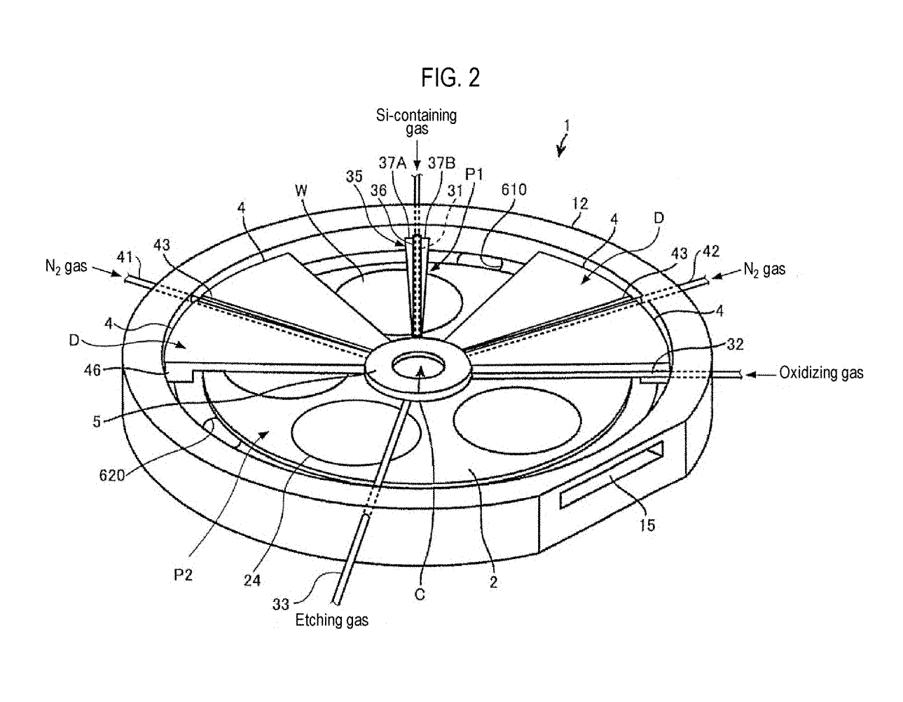

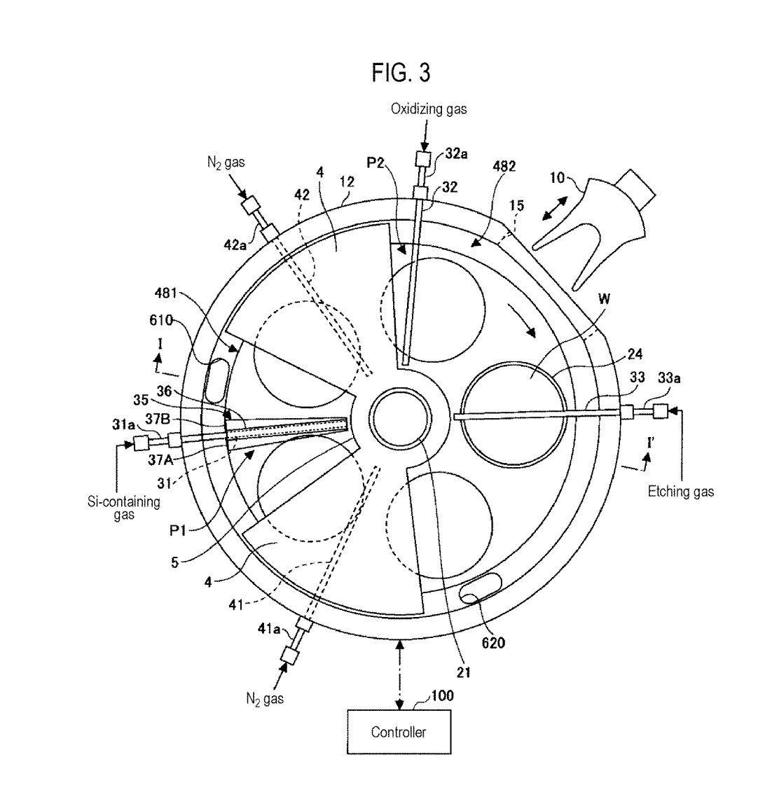

FIG. 1 is a cross-sectional view of an example of a substrate processing apparatus capable of performing an etching method and a method of filling a recessed pattern according to the present embodiment, and FIG. 2 is a perspective view of an example of the substrate processing apparatus capable of performing an etching method and a method of filling a recessed pattern according to the present embodiment. Further, FIG. 3 is a schematic top view of an example of the substrate processing apparatus capable of performing an etching method and a method of filling a recessed pattern according to present embodiment.

Referring to FIGS. 1 to 3, this substrate processing apparatus includes a flat vacuum container (process chamber or chamber) 1 having a substantially circular planar shape, and a rotary table 2 installed in the vacuum container 1 and having the center of rotation at the center of the vacuum container 1. The vacuum container 1 includes a container body 12 having a cylindrical shape with a bottom, and a ceiling plate 11 which is airtightly and detachably disposed on an upper surface of the container body 12 via a seal member 13 (FIG. 1) such as, e.g., an O-ring.

The rotary table 2 is fixed to a cylindrical core portion 21, at its central portion, in which the core portion 21 is fixed to an upper end of a rotary shaft 22 extending in a vertical direction. The rotary shaft 22 penetrates a bottom portion 14 of the vacuum container 1, and has a lower end installed in a driving part 23 that rotates the rotary shaft 22 (FIG. 1) around the vertical axis. The rotary shaft 22 and the driving part 23 are received in a tubular case body 20 whose upper surface is opened. A flange portion provided on the upper surface of the case body 20 is airtightly installed on a lower surface of the bottom portion 14 of the vacuum container 1 so that the airtight state of the internal atmosphere of the case body 20 to the external atmosphere of the case body 20 is maintained.

As illustrated in FIGS. 2 and 3, circular recesses 24 configured to load a plurality of (five in an illustrated example) semiconductor wafers (hereinafter, referred to as “wafers”) W as substrates along the direction of rotation (circumferential direction) are formed on the surface of the rotary table 2. In FIG. 3, for the sake of convenience, the wafer W is illustrated only in one recess 24. The recess 24 has an inner diameter slightly (e.g., 4 mm) larger than a diameter (e.g., 300 mm) of the wafer W, and a depth substantially equal to a thickness of the wafer W. Therefore, when the wafer W is loaded in the recess 24, the surface of the wafer W and the surface of the rotary table 2 (a region where the wafer W is not loaded) have the same height.

FIGS. 2 and 3 are views illustrating an internal structure of the vacuum container 1, in which illustration of the ceiling plate 11 is omitted for convenience of description. As illustrated in FIGS. 2 and 3, first and second film-forming gas nozzles 31 and 32, an etching gas nozzle 33, and isolation gas nozzles 41 and 42, each of which is made of, e.g., quartz, are disposed above the rotary table 2. In the illustrated example, the etching gas nozzle 33, the isolation gas nozzle 41, the first film-forming gas nozzle 31, the isolation gas nozzle 42 and the second film-forming gas nozzle 32 are sequentially arranged at intervals in the circumferential direction of the vacuum container 1 from a transfer port 15 (which will be described later) in a clockwise direction (rotation direction of the rotary table 2). Gas introduction ports 31a, 32a, 33a, 41a and 42a (FIG. 3), which are respective base end portions of these gas nozzles 31, 32, 33, 41 and 42, are fixed to an outer peripheral wall of the container body 12, and are introduced into the vacuum container 1 from the outer peripheral wall of the vacuum container 1. The nozzles are also installed so as to extend parallel to the rotary table 2 along a radial direction of the container body 12.

In the method of filling a recessed pattern according to the present embodiment, for example, an Si-containing gas may be used as a first film-forming gas supplied from the first film-forming gas nozzle 31. As the Si-containing gas, various gases may be used; for example, a trisdimethylaminosilane (TDMAS, SiH(N(CH₃)₂)₃) gas may be used. Furthermore, for example, an oxidizing gas may be used as a second film-forming gas supplied from the second film-forming gas nozzle 32. As the oxidizing gas, an oxygen (O₂) gas and/or an ozone (O₃) gas may be used. Thus, an SiO₂ film can be formed on the wafer W.

When only the etching method according to the present embodiment is carried out, there is no need to perform film formation. Therefore, it is not always necessary to install the first and second film-forming gas nozzles 31 and 32. On the other hand, when the method of filling a recessed pattern according to present embodiment is carried out, it is necessary to perform film formation. Therefore, the first and second film-forming gas nozzles 31 and 32 are installed.

In addition, a fluorine-containing gas or the like used for cleaning or the like may be used as an etching gas supplied from the etching gas nozzle 33; for example, ClF₃ may be used. As the etching gas, a halogen-based gas containing a fluorine-based gas such as CF₄, C₂F₆, CH₃F, CHF₃, Cl₂, ClF₃, BCl₃, NF₃ or the like may be used, but there is no particular limitation as long as it is an etchable gas. That is, various etching gases may be used depending on the application, regardless of the type of etching gas. Also, remote plasma or the like may be mounted as needed to supply an activated etching gas.

In FIGS. 2 and 3, the etching gas nozzle 33 is arranged at a downstream side of the second film-forming gas nozzle 32 in the rotary table 2 in the rotation direction. However, this arrangement may be reversed. That is, the etching gas nozzle 33 may be arranged at an upstream side of the second film-forming gas nozzle 32 in the rotary table 2 in the rotation direction. Also, the relative positions of the second film-forming gas nozzle 32 and the etching gas nozzle 33 are not particularly limited, and the second film-forming gas nozzle 32 and the etching gas nozzle 33 may be arranged at various positions.

As described above, various gases and methods may be adopted as the etching gas and the etching method. For example, etching may be performed by high-temperature etching using an F-containing gas such as ClF₃, or etching may be performed with F radicals by decomposing an F-containing gas such as NF₃ by plasma.

First and second film-forming gas supply sources in which the first and second film-forming gases are stored are respectively connected to the first and second film-forming gas nozzles 31 and 32 via an opening/closing valve and a flow rate controller (both of which are not shown). Also, an etching gas supply source, in which the etching gas is stored, is connected to the etching gas nozzle 33 via an opening/closing valve and a flow rate controller (both of which are not shown).

Various film-forming gases may be used as the first and second film-forming gases depending on a film to be formed. In the present embodiment, a case where a silicon oxide film (SiO₂ film) is formed will be described as an example. In this case, a silicon-containing gas is used as the first film-forming gas. A specific silicon-containing gas is not particularly limited, but it may be possible to preferably use, in addition to the aforementioned TDMAS, for example, an amino silane-based gas such as trisdimethylaminosilane (3DMAS, Si(N(CH₃)₂)₃H), tetrakisdimethylaminosilane (4DMAS, Si(N(CH₃)₂))₄), tetrachlorosilane (TCS, SiCl₄), dichlorosilane (DCS, SiH₂Cl₂), monosilane (SiH₄), hexachlorodisilane (HCD, Si₂Cl₆), or the like.

As described above, an oxidizing gas may be preferably used as the second film-forming gas. An oxygen gas and/or an ozone gas may be preferably used as the oxidizing gas. In particular, since a dense silicon oxide film can be obtained, the oxidizing gas preferably contains an ozone gas.

In the case of forming an SiN film, a silicon-containing gas may be used as the first film-forming gas and an ammonia-containing gas may be used as the second film-forming gas. In the case of forming a TiN film, a TiCl₄ gas may be used as the first film-forming gas and an ammonia-containing gas may be used as the second film-forming gas. In this manner, the first film-forming gas and the second film-forming gas may be determined depending on the kind of a film to be formed. In the etching method and the method of filling a recessed pattern according to the present embodiment, the film to be etched is not particularly limited, and various films may be etched or filled and formed depending on the application.

Furthermore, a supply source of a rare gas such as Ar or He or an inert gas such as an N₂ gas (nitrogen gas) is connected to the isolation gas nozzles 41 and 42 via an opening/closing valve and a flow rate controller (both of which are not shown). The inert gas is not particularly limited, and a rare gas, an N₂ gas or the like may be used as described above. Further, for example, an N₂ gas, may be preferably used. These inert gases are also used as a so-called purge gas.

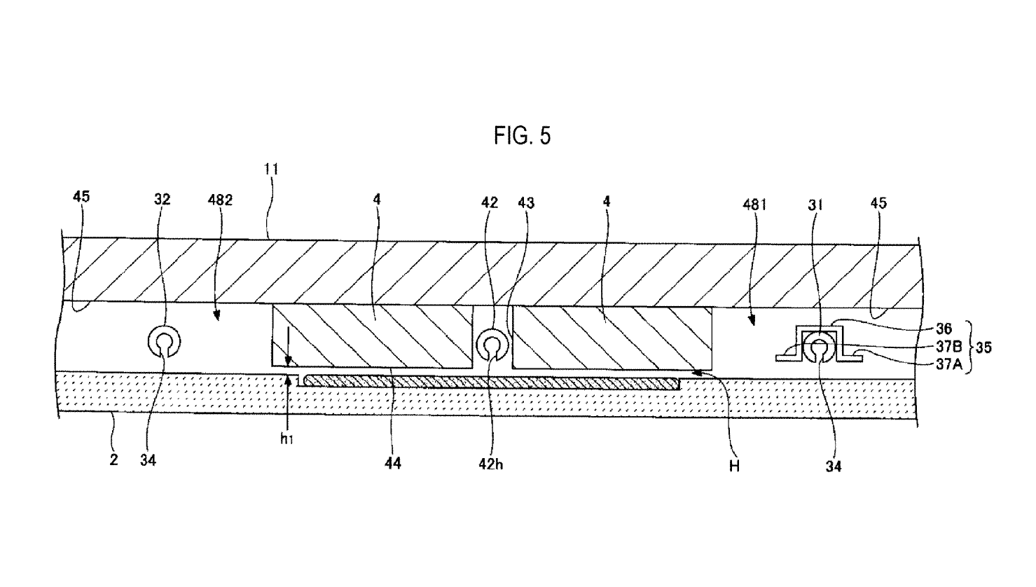

The first and second film-forming gas nozzles 31 and 32 and the etching gas nozzle 33 are formed such that a plurality of gas discharge holes 34 (see FIG. 5) that are opened downward toward the rotary table 2 are arranged along a longitudinal direction of the first and second film-forming gas nozzles 31 and 32 and the etching gas nozzle 33. Although the arrangement of the gas discharge holes 34 is not particularly limited, they may be arranged at intervals of, e.g., 10 mm A lower region of the first film-forming gas nozzle 31 becomes a first processing region P1 for adsorbing the first film-forming gas onto the wafer W. Lower regions of the second film-forming gas nozzle 32 and the etching gas nozzle 33 become a second processing region P2. In the second processing region P2, the second film-forming gas nozzle 32 and the etching gas nozzle 33 coexist, but when performing etching, the second film-forming gas (for example, an oxidizing gas) is not supplied or a purge gas such as a rare gas or an N₂ gas is supplied from the second film-forming gas nozzle 32 while an etching gas is supplied from the etching gas nozzle 33, whereby an etching process can be performed in the second processing region P2. In this case, the first film-forming gas (for example, a silicon-containing gas) is not supplied in the first processing region P1, either or a purge gas such as a rare gas or an N₂ gas is supplied from the first film-forming gas nozzle 31.

On the other hand, when performing film formation, an etching gas is not supplied or a purge gas such as a rare gas or an N₂ gas is supplied from the etching gas nozzles 33, and the first and second film-forming gases are supplied from the first and second film-forming gas nozzles 31 and 32, whereby a film forming process can be performed in the first and second processing regions P1 and P2.

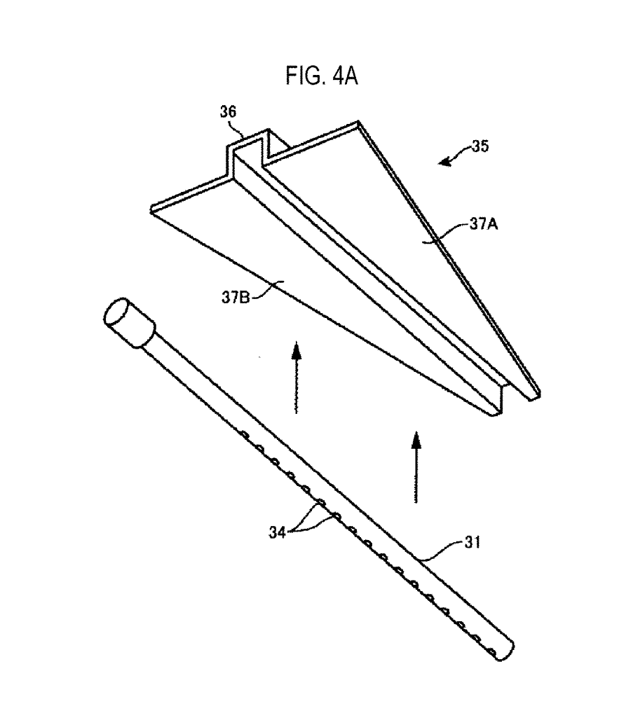

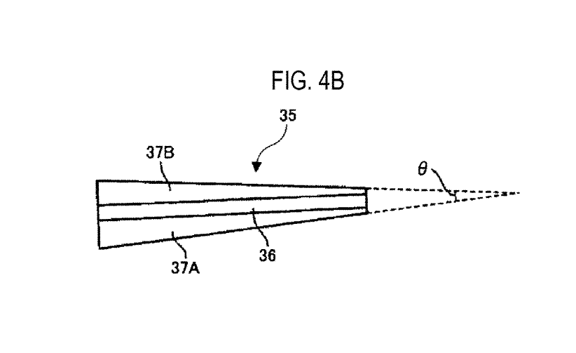

As illustrated in FIGS. 2 and 3, it is desirable that a nozzle cover 35 be installed in the first film-forming gas nozzle 31. Hereinafter, the nozzle cover 35 will be described with reference to FIGS. 4A and 4B. The nozzle cover 35 has a base portion 36 extending along the longitudinal direction of the first gas nozzle 31 and having a one side-opened rectangular sectional shape. The base portion 36 is arranged so as to cover the first film-forming gas nozzle 31. A flow rectifying plate 37A is formed at one of two opening ends extending in the longitudinal direction of the base portion 36 and a flow rectifying plate 37B is formed at the other opening end. In the present embodiment, the flow rectifying plates 37A and 37B are formed parallel to the upper surface of the rotary table 2. Also, in the present embodiment, as illustrated in FIGS. 2 and 3, the flow rectifying plate 37A is arranged at the upstream side of the first film-forming gas nozzle 31 in the rotation direction of the rotary table 2 and the flow rectifying plate 37B is arranged at the downstream side thereof.

As clearly indicated in FIG. 4B, the flow rectifying plates 37A and 37B are formed symmetrically to the central axis of the first film-forming gas nozzle 31. The length of the flow rectifying plates 37A and 37B along the rotation direction of the rotary table 2 is increased toward the outer periphery of the rotary table 2 so that the nozzle cover 35 has a substantially fan-like planar shape. Here, an opening angle θ of the fan indicated by a dotted line in FIG. 4B is determined in consideration of the size of a convex portion 4 (isolation region D) as described hereinbelow, but it is desirable that it be, for example, 5° or more and less than 90°, and specifically, it is more desirable that it be, for example, 8° or more and less than 10 °.

In the present embodiment, there has been described an example in which the nozzle cover 35 is installed only in the first film-forming gas nozzle 31, but the same nozzle cover 35 may also be installed in the second film-forming gas nozzle 32 and the etching gas nozzle 33A.

Referring to FIGS. 2 and 3, two convex portions 4 are provided in the vacuum container 1. The convex portions 4 each have a substantially fan-like planar shape whose top portion is cut into an arc shape, and in the present embodiment, the inner circular arc is connected to a protrusion 5 (which will be described later) and the outer circular arc is arranged so as to face the inner peripheral surface of the container body 12 of the vacuum container 1. FIG. 5 illustrates a cross section of the vacuum container 1 along the concentric circle of the rotary table 2 from the first film-forming gas nozzle 31 to the second film-forming gas nozzle 32. As illustrated in the drawing, the convex portion 4 is formed on the rear surface of the ceiling plate 11. Therefore, a flat low ceiling surface 44 (a first ceiling surface), which is a lower surface of the convex portion 4, and a ceiling surface 45 (a second ceiling surface), which is positioned on both sides of the ceiling surface 44 in the circumferential direction and which is higher than the ceiling surface 44, exist in the vacuum container 1.

In addition, as illustrated in FIG. 5, a groove portion 43 is formed at the center of the convex portion 4 in the circumferential direction, in which the groove portion 43 extends along the radial direction of the rotary table 2. The isolation gas nozzle 42 is received in the groove portion 43. Similarly, a groove portion 43 is formed in another convex portion 4, and the isolation gas nozzle 41 is received therein. Furthermore, reference numeral 42h illustrated in the drawing is a gas discharge hole formed in the isolation gas nozzle 42. A plurality of gas discharge holes 42h are formed at predetermined intervals (e.g., 10 mm) along the longitudinal direction of the isolation gas nozzle 42. An opening diameter of the gas discharge hole 42h may be, for example, 0.3 to 1.0 mm. Although not illustrated, gas discharge holes may also be formed in the isolation gas nozzle 41.

The first film-forming gas nozzle 31 and the second film-forming gas nozzle 32 are respectively installed in right and left spaces 481 and 482 below the high ceiling surface 45. The first and second film-forming gas nozzles 31 and 32 are installed near the wafer W away from the ceiling surface 45. As illustrated in FIG. 5, the space 481 below the high ceiling surface 45 where the first film-forming gas nozzle 31 is installed and the space 482 below the high ceiling surface 45 where the second film-forming gas nozzle 32 is installed are also provided.

The low ceiling surface 44 forms an isolation space H which is a narrow space with respect to the rotary table 2. When an inert gas, for example, an N₂ gas, is supplied from the isolation gas nozzle 42, the N₂ gas flows toward the spaces 481 and 482 through the isolation space H. At this time, since the volume of the isolation space H is smaller than that of the spaces 481 and 482, the pressure of the isolation space H can become higher than that of the spaces 481 and 482 by the N₂ gas. That is, the isolation space H provides a pressure barrier between the spaces 481 and 482. Furthermore, the N₂ gas flowing out from the isolation space H into the spaces 481 and 482 acts as a counter flow for the first film-forming gas from the first processing region P1 and the second film-forming gas from the second processing region P2. Thus, the first film-forming gas from the first processing region P1 and the second film-forming gas from the second processing region P2 are isolated by the isolation space H. Accordingly, it is possible to suppress mixing reaction of the first film-forming gas and the second film-forming gas in the vacuum container 1. Even when the etching gas is supplied, the isolation space H also prevents the etching gas from flowing into the first processing region P1.

It is desirable that a height h1 of the ceiling surface 44 with respect to the upper surface of the rotary table 2 be set at an appropriate height in consideration of the internal pressure of the vacuum container 1, the rotation speed of the rotary table 2, the supply amount of isolation gas (N₂ gas), or the like during film formation so that the pressure of the isolation space H is higher than that of the spaces 481 and 482.

As described above, since the isolation region D in which the isolation space H is formed may also be referred to as a region for supplying the purge gas to the wafer W, it may be referred to as a purge gas supply region.

Referring back to FIGS. 1 to 3, the protrusion 5 is formed on the lower surface of the ceiling plate 11 so as to surround the outer periphery of the core portion 21 for fixing the rotary table 2. In the present embodiment, the protrusion 5 is continuous with a portion of the convex portion 4 at the center side of rotation, in which the lower surface of the protrusion 5 is formed at the same height as the ceiling surface 44.

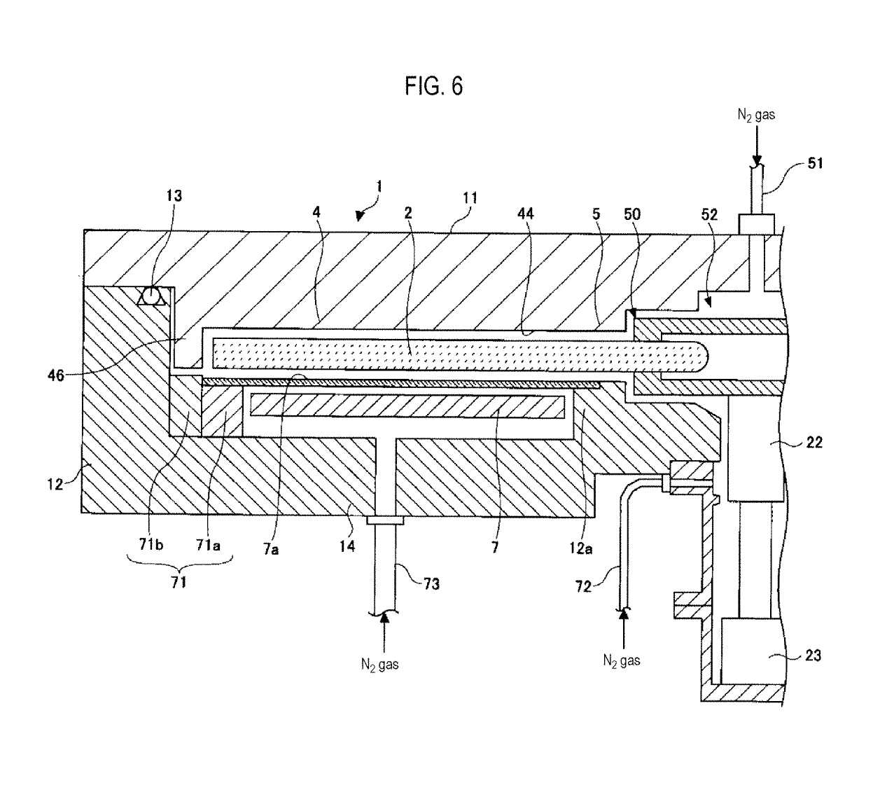

FIG. 1 referred to above is a cross-sectional view taken along line I-I′ in FIG. 3, illustrating a region where the ceiling surface 45 is formed, while FIG. 6 is a partial cross-sectional view illustrating a region where the ceiling surface 44 is formed. As illustrated in FIG. 6, a bent portion 46 that bends in an L shape so as to face an outer end surface of the rotary table 2 may be formed in a peripheral portion (a portion on an outer edge side of the vacuum container 1) of the substantially fan-like convex portion 4. The bent portion 46 can suppress a gas from flowing between the spaces 481 and 482 (FIG. 5) through the space between the rotary table 2 and the inner peripheral surface of the container body 12. Since the fan-like convex portion 4 is formed on the ceiling plate 11 and the ceiling plate 11 is configured to be detachable from the container body 12, there is a slight gap between the outer peripheral surface of the bent portion 46 and the container body 12. The gap between the inner peripheral surface of the bent portion 46 and the outer end surface of the rotary table 2 and the gap between the outer peripheral surface of the bent portion 46 and the container body 12 may be set to, for example, a dimension similar to the height of the ceiling surface 44 with respect to the upper surface of the rotary table 2.

Referring back to FIG. 3, a first exhaust port 610 communicating with the space 481 and a second exhaust port 620 communicating with the space 482 are formed between the rotary table 2 and the inner peripheral surface of the container body. The first exhaust port 610 and the second exhaust port 620 are each connected to, for example, a vacuum pump 640, which is a vacuum exhaust means, via an exhaust pipe 630, as illustrated in FIG. 1. Furthermore, in FIG. 1, a pressure regulator 650 is installed.

As illustrated in FIGS. 1 and 6, a heater unit 7 which is a heating means may be installed in the space between the rotary table 2 and the bottom portion 14 of the vacuum container 1 to heat the wafer W on the rotary table 2 to a temperature determined by the process recipe through the rotary table 2. In order to suppress a gas from entering the space below the rotary table 2, a ring-shaped cover member 71 is installed in the lower side near the periphery of the rotary table 2. As illustrated in FIG. 6, the cover member 71 may be configured to include an inner member 71a installed so as to face an outer edge portion of the rotary table 2 and a portion positioned radially outward than the outer edge portion, from the lower side, and an outer member 71b installed between the inner member 71a and the inner wall surface of the vacuum container 1. The outer member 71b is installed close to the bent portion 46 below the bent portion 46 formed in the outer edge portion of the convex portion 4, and the inner member 71a is installed under the outer edge portion of the rotary table 2 (and the portion positioned radially outward than the outer edge portion) so as to surround the entire circumference of the heater unit 7.

As illustrated in FIG. 1, a portion of a bottom portion 14 at a portion closer to the center of rotation than the space where the heater unit 7 is disposed forms a protrusion 12a so as to protrude upward to approach the core portion 21 near the central portion of the lower surface of the rotary table 2. A narrow space is formed between the protrusion 12a and the core portion 21. In addition, a gap between the inner peripheral surface of a through hole of the bottom portion 14 penetrating the bottom portion 14 and the rotary shaft 22 is narrowed. This narrow space communicates with the case body 20. A purge gas supply pipe 72 for supplying an N₂ gas as a purge gas into the narrow space and purging it is installed in the case body 20. Furthermore, a plurality of purge gas supply pipes 73 for purging the arrangement space of the heater unit 7 are installed in the bottom portion 14 of the vacuum container 1 at predetermined angular intervals in the circumferential direction below the heater unit 7 (in FIG. 6, only one purge gas supply pipe 73 is illustrated). In addition, in order to suppress the entry of a gas into the region where the heater unit 7 is installed, a cover member 7a is installed between the heater unit 7 and the rotary table 2 so as to cover along the circumferential direction between the inner peripheral wall of the outer member 71b (the upper surface of the inner member 71a) and the upper end portion of the protrusion 12a. The cover member 7a may be made of, e.g., quartz.

When an N₂ gas is supplied from the purge gas supply pipe 72, this N₂ gas flows through the space between the rotary table 2 and the cover member 7a via the gap between the inner peripheral surface of the through hole of the bottom portion 14 and the rotary shaft 22 and the gap between the protrusion 12a and the core portion 21, and is exhausted from the first exhaust port 610 or the second exhaust port 620 (FIG. 3). Furthermore, when the N₂ gas is supplied from the purge gas supply pipe 73, this N₂ gas flows out from the space where the heater unit 7 is received through a gap (not shown) between the cover member 7a and the inner member 71a, and is exhausted from the first exhaust port 610 or the second exhaust port 620 (FIG. 3). Due to these flows of the N₂ gas, it is possible to suppress the mixing of the gases in the space 481 and the space 482 through the space below the center of the vacuum container 1 and the space below the rotary table 2.

Furthermore, since the isolation gas supply pipe 51 is connected to the central portion of the ceiling plate 11 of the vacuum container 1, it may be configured such that the N₂ gas as an isolation gas is supplied to the space 52 between the ceiling plate 11 and the core portion 21. The isolation gas supplied to the space 52 is discharged through the narrow space 50 (FIG. 6) between the protrusion 5 and the rotary table 2 toward the periphery along the surface of the rotary table 2 on the wafer loading region side. The space 50 can be maintained at a higher pressure than that of the space 481 and the space 482 by the isolation gas. Thus, the first film-forming gas supplied to the first processing region P1 and the second film-forming gas and the etching gas supplied to the second processing region P2 are suppressed from passing through the central region C to be mixed. That is, the space 50 (or the central region C) can function similarly to the isolation space H (or the isolation region D).

In addition, as illustrated in FIGS. 2 and 3, the transfer port 15 for transferring the wafer W as the substrate between the external transfer arm 10 and the rotary table 2 may be formed on a sidewall of the vacuum container 1. The transfer port 15 may be opened and closed by a gate valve (not shown). In this case, the recess 24, which is the wafer loading region of the rotary table 2, is configured to transfer the wafer W to and from the transfer arm 10 at a position facing the transfer port 15. Therefore, transfer lift pins for lifting the wafer W from the rear surface through the recess 24 and their elevating mechanism (both of which are not shown) are installed at a portion corresponding to the transfer position on the lower side of the rotary table 2.

As illustrated in FIG. 1, a controller 100 configured as a computer for controlling the entire operation of the apparatus may be installed in the substrate processing apparatus according to the present embodiment. A program that causes the substrate processing apparatus to perform a substrate processing method as described hereinbelow under the control of the controller 100 may be stored in a memory of the controller 100. This program has a group of steps configured to execute a substrate processing method as described hereinbelow and is stored in a medium 102 such as a hard disk, a compact disc, a magneto-optical disc, a memory card, a flexible disk or the like. Thus, the program is read by a predetermined reading device into the storage part 101 and may be installed in the controller 100.

### [Substrate Processing Method]

Next, an etching method and a method of filling a recessed pattern according to an embodiment of the present disclosure using the aforementioned substrate processing apparatus will be described. The etching method and the method of filling a recessed pattern according to the present embodiment are applicable to various films, but in the present embodiment, etching and filling film formation of a silicon oxide film will be described. Further, the components as described above are denoted by the same reference numerals as those of the substrate processing apparatus according to the aforementioned embodiment, and a description thereof will be omitted.

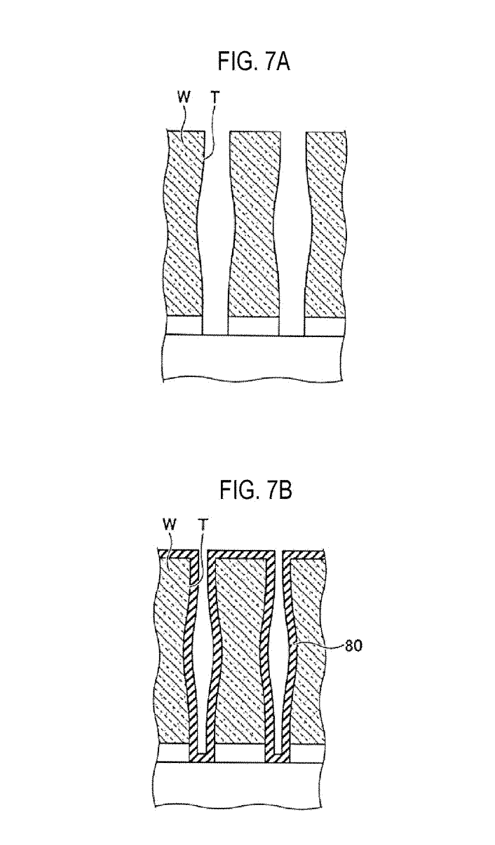

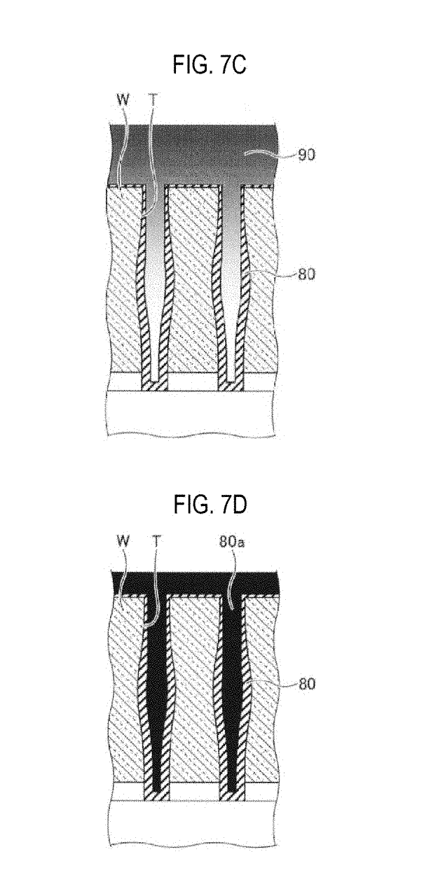

FIGS. 7A to 7D are views illustrating a series of processes of a method of filling a recessed pattern including an etching method according to an embodiment of the present disclosure.

FIG. 7A is a view illustrating an example of a sectional shape of a trench T formed on a wafer W before film formation. In FIGS. 7A to 7D, a case where a recessed pattern formed on a surface of the wafer W is the trench T will be described as an example. However, the recessed pattern may be a via hole or an irregular shape. Further, a case where the wafer W is a silicon wafer will be described as an example, it may be a wafer W made of other silicon compounds.

In FIG. 7A, the sectional shape of the trench T has a shape whose width of the center (middle) portion is wider than that of the upper portion and the bottom portion in the depth direction. When the trench T is formed by wet etching, the phenomenon that the central portion in the depth direction is more recessed than the upper portion and the bottom portion to widen the width of the pattern often occurs. The wafer W having the trench T whose width of the central portion in the sectional shape is widened is formed on its surface is loaded into the vacuum container 1.

Specifically, in the substrate processing apparatus described with reference to FIGS. 1 to 6, a gate valve (not shown) is opened, and as illustrated in FIGS. 2 and 3, the wafer W is transferred by the transfer arm 10 from the outside into the recess 24 of the rotary table 2 via the transfer port 15. This transfer is carried out by lifting and lowering a lift pin (not shown) from the bottom side of the vacuum container 1 via the through hole on the bottom surface of the recess 24 when the recess 24 stops at a position facing the transfer port 15. Such transfer of the wafer W is performed by intermittently rotating the rotary table 2 so as to load the wafer W in each of the five recesses 24 of the rotary table 2.

Subsequently, the gate valve is closed and the interior of the vacuum container 1 is vacuumized by the vacuum pump 640. Thereafter, an N₂ gas as an isolation gas is discharged from the isolation gas nozzles 41 and 42 at a predetermined flow rate, and an N₂ gas is also discharged from the isolation gas supply pipe 51 and the purge gas supply pipes 72 and 73 at a predetermined flow rate. According to this, the interior of the vacuum container 1 is adjusted to a preset processing pressure by the pressure regulation means 650. Next, the wafer W is heated by the heater unit 7 to, for example, 620 degrees C., while rotating the rotary table 2 clockwise at a rotation speed of, e.g., 120 rpm.

FIG. 7B is a view illustrating an example of a first film forming process. In the first film forming process, a conformal film 80 that conforms to the shape of the trench T is formed by atomic layer deposition (ALD). Although the film 80 may be various types of films, an example in which an SiO₂ film is formed will be described here.

In the first film forming process, an Si-containing gas is supplied from the first film-forming gas nozzle 31 and an oxidizing gas is supplied from the second film-forming gas nozzle 32. An N₂ gas is supplied as a purge gas or no gas is supplied from the etching gas nozzle 33. Although various gases may be used as the Si-containing gas, an example using TDMAS will be described in the present embodiment. Also, although various gases may be used as the oxidizing gas, an example using an ozone gas will be described here.

When the wafer W passes through the first processing region P1, TDMAS as a raw material gas is supplied from the first film-forming gas nozzle 31 and is adsorbed onto the surface of the wafer W. The wafer W on which the TDMAS is adsorbed onto the surface passes through the isolation region D having the isolation gas nozzle 42 by the rotation of the rotary table 2 and is purged, and then enters the second processing region P2. In the second processing region, an ozone gas is supplied from the second film-forming gas nozzle 32, the Si component contained in the TDMAS is oxidized by the ozone gas, and SiO₂ as a reaction product is deposited on the surface of the wafer W including the trench T. The wafer W that has passed through the second processing region P2 passes through the isolation region D having the isolation gas nozzle 41 and is purged, and then enters the first processing region P1. Here, TDMAS is also supplied from the first film-forming gas nozzle 31, and is adsorbed onto the surface of the wafer W. By repeating the same cycle therefrom, SiO₂ as a reaction product is deposited on the surface of the wafer W to form an SiO₂ film. Atomic layers (precisely, molecular layers) of the SiO₂ film are sequentially deposited by repeating a cycle in which the raw material gas (TDMAS) and the oxidizing gas (ozone) are alternately supplied to the surface of the wafer W, to form the conformal film 80 that conforms to the surface shape of the wafer W including the trench T by ALD. Since the film is the conformal film 80, the shape of the trench T whose width of the middle portion is wider than those of the upper portion and the bottom portion becomes a surface shape of the film 80 as it is. If the ALD film formation is continued like this, since the gap in the middle portion is larger than those of the upper portion and the bottom portion, there may be a possibility that upper portion is first closed and a void will be generated in the central portion.

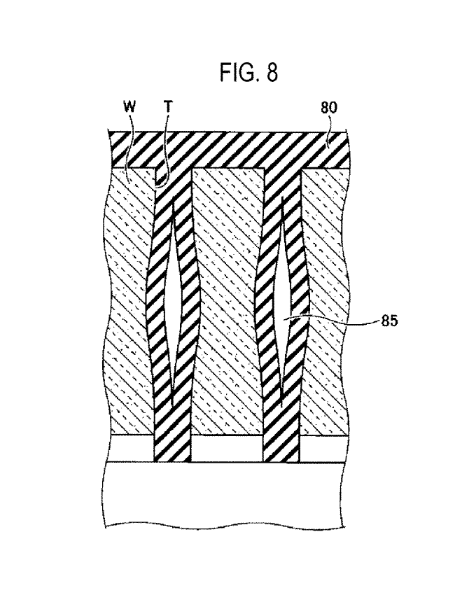

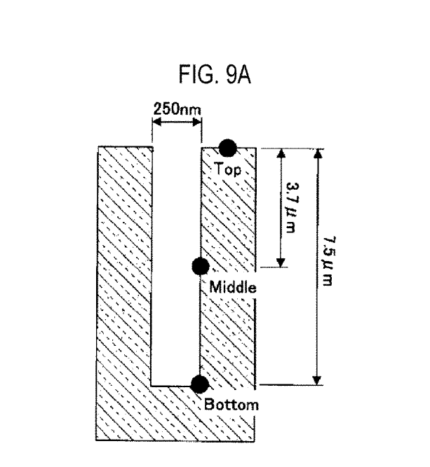

FIG. 8 is a view illustrating an example of a conventional film forming method in which such a void is generated. As illustrated in FIG. 8, if a trench T whose width of middle portion in a sectional shape is wider than that of the upper portion is filled with a conformal film 80, when the upper portion of the trench T is closed, there may be a possibility that a void 85 may be generated inside the trench T and an insufficient filling is made.

Therefore, in the method of filling a recessed pattern according to the present embodiment, after the film forming process illustrated in FIG. 7B, an etching process of etching only the upper portion of the trench T is performed to widen the opening of the upper portion of the trench T, forming the sectional shape of the surface of the film 80 in a V shape.

FIG. 7C is a view illustrating an example of the etching process. In the etching process, etching is performed so that the etching rate of the upper portion of the trench T in the depth direction of the trench T is sufficiently higher than the etching rate of the central portion and the bottom portion of the trench.

In order to perform such etching, the interior of the vacuum container 1 is firstly set to such conditions that the etching gas is consumed in the upper portion of the trench T and does not reach much the inside of the trench T, and etching is performed under the conditions.

First, the supply of TDMAS from the first film-forming gas nozzle 31 and the supply of the ozone gas from the second film-forming gas nozzle 32 are stopped upon completion of the first film forming process illustrated in FIG. 7B. The supply of the gases from the first and second film-forming gas nozzles 31 and 32 may be stopped as it is or an inert gas such as an N₂ gas may be supplied therefrom.

When the first film-forming process of FIG. 7B is completely terminated, setting the conditions for the etching process are performed. Specifically, the rotation speed of the rotary table 2 is set at a predetermined high speed and the internal pressure of the vacuum container 1 is set at a predetermined high pressure so that the etching gas does not reach much inside the trench T.

Here, the reason why the rotation speed of the rotary table 2 is set high is that it is more difficult for the etching gas to reach the inside of the trench T when the rotation speed of the rotary table 2 is high. That is, when the rotary table 2 is rotated at a high speed, the contact time with the etching gas supplied from the etching gas nozzle 33 is shortened and the wafer W may reach the isolation region D while the etching gas stays on the surface, thereby making it difficult for the etching gas to reach the depth of the trench T.

The reason why the internal pressure of the vacuum container 1 is set high is to suppress entering of the etching gas to the inside of the trench T by suppressing the diffusion of the etching gas by means of shortening the mean free path of the molecules of the etching gas.

By setting the rotation speed of the rotary table 2 at a high speed and setting the internal pressure of the vacuum container 1 at a high pressure in this way, the two conditions can cooperate to make it difficult for the etching gas to enter the inside of the trench T.

Although the rotation speed of the rotary table 2 may be set to various values depending on the application, for example, if it is set to 120 rpm in the film forming process, it may be set at a predetermined rotation speed within a range of 60 to 700 rpm, preferably at a predetermined rotation speed within a range of 140 to 300 rpm, for example, at a rotation speed of 180 rpm. Similarly, the internal pressure of the vacuum container 1 may be set at a predetermined pressure within a range of, for example, 1 to 20 Torr, preferably at a predetermined pressure within a range of 4 to 8 Torr, specifically to 5 Torr.

By setting two or more parameters to a condition under which the etching gas is difficult to enter the inside of the trench T, the two parameters can cooperate to effectively suppress the etching gas from entering the inside of the trench T.

After setting to these conditions, the etching gas is supplied from the etching gas nozzle 33. As the etching gas, various etching gases may be used as long as the film 80 can be appropriately etched; for example, a gas containing fluorine may be used. In the present embodiment, an example in which ClF₃ is used as the etching gas will be described. By setting the interior of the vacuum container 1 at a predetermined high pressure and supplying ClF₃ from the etching gas nozzle to the wafer W while rotating the rotary table 2 at a predetermined high speed, as illustrated in FIG. 7C, an etching gas 90 is consumed near the surface of the wafer W and the upper portion of the trench T and the film 80 can be etched in a state in which the etching gas does not reach the inside of the trench T. Thus, it is possible to form the film 80 having a V-shaped sectional shape in the trench T, and to sufficiently widen the opening of the upper portion of the trench T by such a V-shaped sectional shape.

Furthermore, when the etching process is completed, the supply of the etching gas 90 from the etching gas nozzle 33 is stopped. The etching gas nozzle 33 may remain in a state where the supply of the etching gas is stopped as it is or instead an inert gas such as N₂ may be supplied therefrom.

FIG. 7D is a view illustrating an example of a second film forming process. In the second film forming process, the interior of the vacuum container 1 is again set to the same conditions as those of the first film forming process, to perform filling film formation in which a film 80a is filled in the trench T in which the film 80 having the V shape is formed. The film 80 and the film 80a are the same type, and an SiO₂ film is filled in the trench T. Finally, the trench T is filled with the SiO₂ film.

Since the second film forming process may be performed under the same conditions as those of the first film forming process, in the present embodiment, the rotation speed of the rotary table 2 is set to 120 rpm and the internal pressure of the vacuum container 1 is again set to 6.7 Torr. TDMAS is supplied from the first film-forming gas nozzle 31 and an ozone gas is supplied from the second film-forming gas nozzle 32.

The conformal film 80a is formed by the ALD film formation, and since the film 80 has a V-shaped sectional shape, the opening at the upper portion of the trench T is kept in a large opened state so that the trench T can be filled with the films 80 and 80a without generating the void 85 therein.

As described above, according to the method of filling a recessed pattern of present embodiment, it is possible to fill the inside of the trench T with the films 80 and 80a without generating the void 85. If the inside of the trench T is filled with the films 80 and 80a, the supply of the film-forming gases from the film-forming gas nozzles 31 and 32 is stopped, the rotary table 2 is also stopped, the wafer W is unloaded in reverse order of the loading, and the processing of the wafer W is completed.

Here, when the opening of the trench T is closed during the execution of the second film forming process, the etching process of FIG. 7C and the second film forming process of FIG. 7D may be repeated multiple times. This makes it possible to form the V-shaped sectional shape again, and to perform filling film formation without generating a void.

Also, as described above, the etching process may be performed using an activated etching gas obtained by activating the etching gas with a remote plasma device or the like. In this case, the activated etching gas may be supplied using a shower head instead of the etching gas nozzle 33.

In addition, when performing the first and/or the second film forming process, the film 80 may be modified by plasma. In this case, an oxidizing gas may be activated and supplied by inductively coupled plasma (ICP). In this manner, the supply of the etching gas and the film-forming gas may be performed in various ways depending on the application.

It is common to the conventional method of filling a recessed pattern that the etching process is performed by an external etching apparatus, not in the vacuum container 1 of the substrate processing apparatus. However, in the method of filling a recessed pattern according to the present embodiment, the film forming-etching-film forming processes may be sequentially performed in-situ in the same vacuum container 1. Thus, it is possible to improve the throughput, and to perform the filling film formation of the trench T without generating the void 85, thereby improving both the quality and the productivity.

In addition, since it is also possible to perform the filling film formation even with respect to the trench T illustrated in FIGS. 7A to 7D whose width of the middle portion is wider than that of the upper portion without generating the void 85, the filling film formation of high quality can be carried out on the wafer W having various patterns.

Next, results of experiments conducted by the inventors to create the present disclosure will be described.

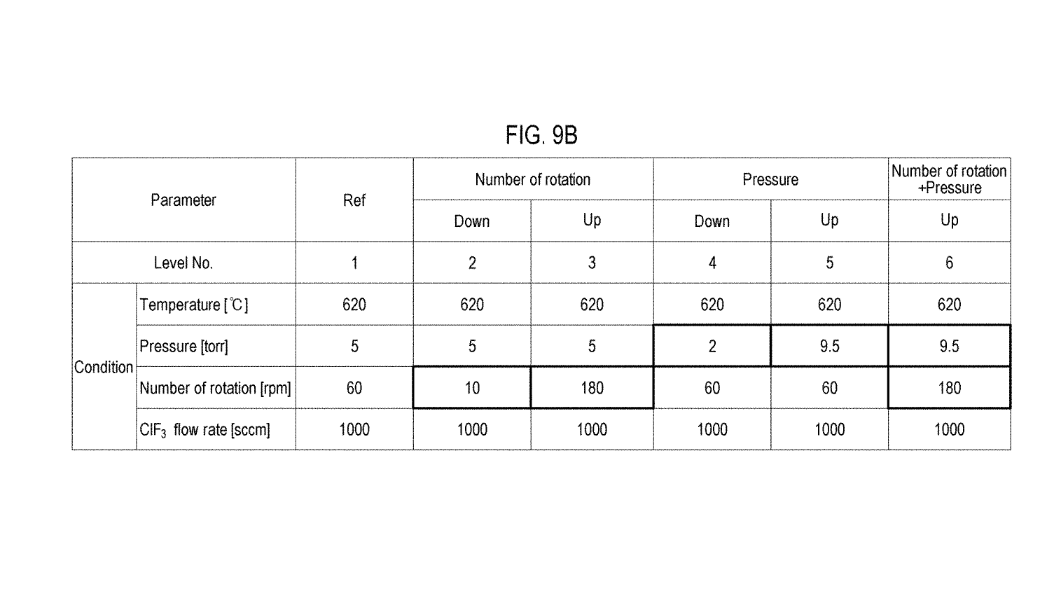

FIGS. 9A and 9B are tables illustrating etching conditions performed to find the validity of parameters and effective setting values related to the etching method according to the present embodiment.

FIG. 9A is a diagram illustrating a shape and measurement positions of a sample used in experiments. As illustrated in FIG. 9A, a trench T having an opening width of 250 nm and a depth of 7.5 μm was used as the sample, and respective measurement points were set by using a top surface of a wafer W as Top, a position at a depth of 3.7 μm from the surface as Middle, and a bottom surface at a depth of 7.5 μm from the surface as Bottom. An aspect ratio is 30. Furthermore, the center position of the wafer W was used as the position of the sample.

As the etching conditions, the temperature of the wafer W was set at 620 degrees C., ClF₃ was used as the etching gas, and the flow rate was set at 1,000 sccm. Experiments were conducted by variously setting the internal pressure of the vacuum container 1 and the rotation speed of the rotary table 2 as parameters.

FIG. 9B is a list of parameters set in experiments. As described above, the etching conditions were a temperature, a pressure, a rotation speed, and a flow rate of ClF₃, in which the temperature was fixed to 620 degrees C. and the flow rate of ClF₃ was fixed to 1,000 sccm. The experiments were conducted by setting the pressure to 5 Torr as a reference standard pressure and setting a lower set value to 2 Torr and a higher set value to 9.5 Torr. Furthermore, the rotation speed of the rotary table was set to 60 rpm as a reference, in which a lower set value was set to 10 rpm and a higher set value was set to 180 rpm.

As illustrated in FIG. 9B, the experiments were conducted for five settings, such as when only the rotation speed is lowered (level No. 2), when only the rotation speed is increased (level No. 3), when only pressure is lowered (level No. 4), when only pressure is raised (level No. 5), and when both the rotation speed and the pressure are raised (level No. 6), with respect to the reference (level No. 1).

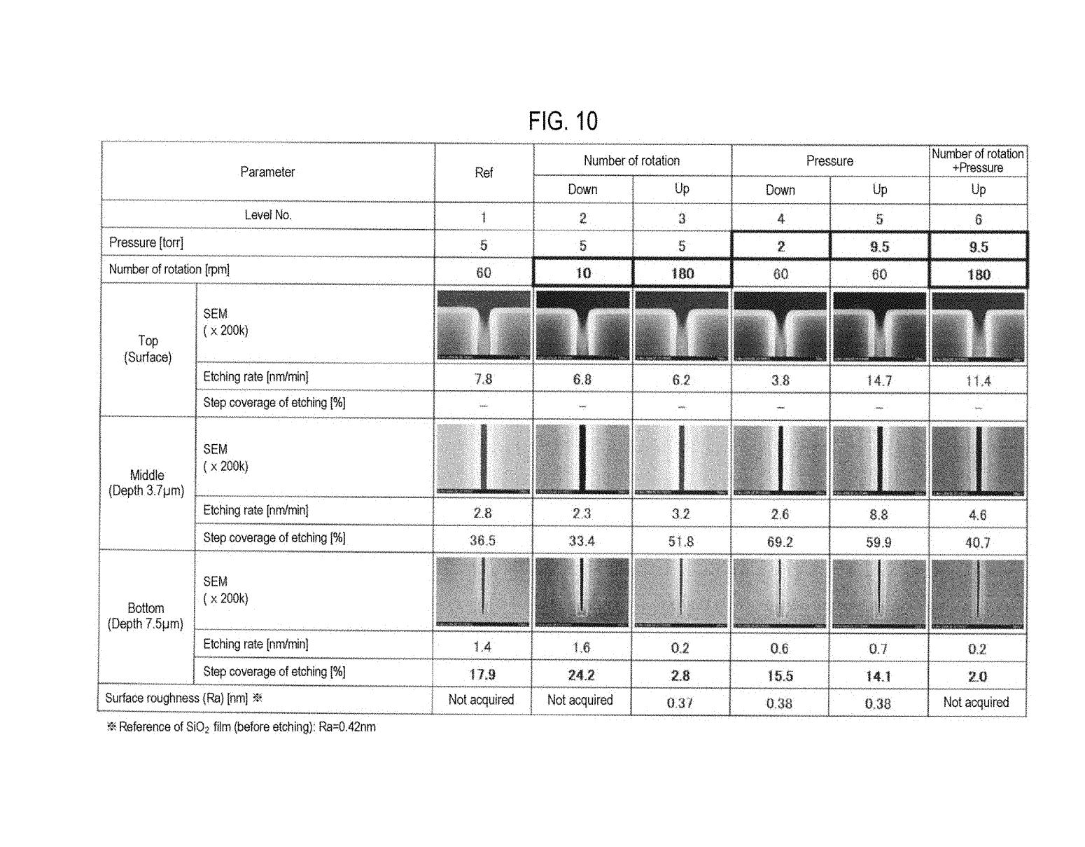

FIG. 10 is a table illustrating SEM images and measured values after etching for the level Nos. 1 to 6 in FIGS. 9A and 9B.

In FIG. 10, SEM images, etching rates (nm/min), and step coverages (%) of etching at the measurement points Top, Middle and Bottom of each level are illustrated. In order to form a V-shaped sectional shape, it is desirable that the etching rate of Top be high and the etching rate of Bottom be low.

In the reference level No. 1 where the pressure was set to 5 Torr and the rotation speed of the rotary table 2 was set to 60 rpm, the etching rate of Top was 7.8 (nm/min) and the etching rate of Bottom was 1.4 (nm/min).

In the level No. 2 where only the rotation speed of the rotary table 2 was lowered to 10 rpm from the reference, the etching rate of Top was 6.8 (nm/min) and the etching rate of Bottom was 1.6 (nm/min). The result was worsened as the V shape became weaker than the reference. From the result, it is considered to be difficult to form the V-shaped sectional shape when the rotation speed of the rotary table 2 was lowered.

In the levels No. 3 where only the rotation speed of the rotary table 2 was raised to 180 rpm from the reference, the etching rate of Top was 6.2 (nm/min) which was lower than the reference, but the etching rate of Bottom was drastically lowered to 0.2 (nm/min). Thus, it can be seen that the V-shaped sectional shape was better obtained than the reference. Based on the results of the level Nos. 2 and 3, it can be seen that increasing the rotation speed of the rotary table 2 makes it easier to form the V-shaped sectional shape.

In the level No. 4 where only the pressure of the vacuum container 1 was lowered to 2 Torr from the reference, the etching rate of Top was lowered to 3.8 (nm/min) and the etching rate of Bottom was lowered to 0.6 (nm/min). The reduction of Bottom was large, but the etching rate of Top was also smaller than ½ of the reference. Thus, since the reduced amount was large, this result is considered that the V-shaped sectional shape was not obtained. From the result, it is considered that it is difficult to form the V-shaped sectional shape when the pressure of the vacuum container 1 was lowered.

In the level No. 5 where only the pressure of the vacuum container 1 was raised to 9.5 Torr from the reference, the etching rate of Top was 14.7 (nm/min) which was much more increased than the reference. In addition, since the etching rate of Bottom was also lowered to 0.7 (nm/min), it can be seen that the V-shaped sectional shape was better obtained than the reference. Based on the results of the levels Nos. 4 and 5, it can be seen that increasing the pressure of the vacuum container 1 makes it easier to form the V-shaped sectional shape.

In the level No. 6 where the pressure of the vacuum container 1 was raised to 9.5 Torr and the rotation speed of the rotary table 2 was increased to 180 rpm from the reference, the etching rate of Top was 11.4 (nm/min) which was much more increased than the reference, and the etching rate of Bottom was set to 0.2 (nm/min) which was much more lowered than the reference. It can be seen that the V-shaped sectional shape was better obtained than the reference. The etching rate of Top was 11.4 (nm/min) which was slightly lower than 14.7 (nm/min) of the level No. 5 where only the pressure of the vacuum container 1 was raised, but the etching rate of Bottom was 0.2 (nm/min) which was drastically lower than 0.7 (nm/min) of the level No. 5. Therefore, it can be seen that the V-shaped sectional shape was better obtained than the level No. 5 as a whole.

By raising the pressure of the vacuum container 1 and increasing the rotation speed of the rotary table 2 in this way, it is possible to perform V-shaped etching to obtain the V-shaped sectional shape. That is, it was recognized that by changing two parameters effective for forming the V-shaped sectional shape, better results can be obtained than by adjusting with only one parameter.

Furthermore, instead of these, in order to consume the etching gas near the surface of the wafer W, it is also effective to lower the flow rate of the etching gas or lower the flow velocity of the etching gas. When lowering the flow rate of the etching gas, a state in which the etching gas is insufficient is created, whereby the etching gas is not widely spread to the inside of the trench T and the amount of etching gas consumed near the surface of the wafer W is increased. In addition, when lowering the flow velocity of the etching gas, the intensity of the etching gas is weakened, thereby suppressing the etching gas from reaching the inside of the trench T. By adjusting two or more of these parameters in combination, it is possible to perform V-shaped etching to form the V-shaped sectional shape.

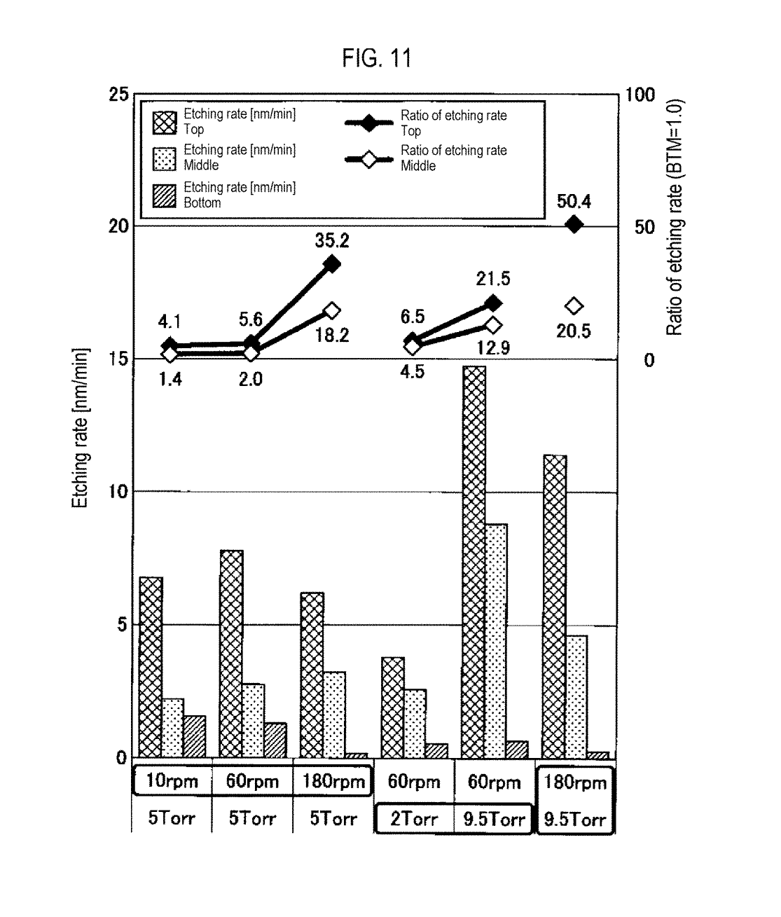

FIG. 11 is a graph illustrating the evaluation results illustrated in FIG. 10. In FIG. 11, the vertical axis indicates an etching rate, and the etching rates of Top, Middle and Bottom in each of the levels Nos. 1 to 6 are indicated in the order of Top, Middle and Bottom, starting from the left in the bar graph. As described with reference to FIG. 10, in the level No. 5 where only the pressure was raised, the etching rate of Top is the highest, but the etching rate of Bottom is also slightly high. On the other hand, in the level No. 6 where both the pressure and the rotation speed were increased, although the etching rate of Top is slightly lower than that of the level No. 5, the etching rate of Bottom is also low. Accordingly, it can be seen that the best V-shaped sectional shape was obtained as a whole.

It can be seen that by changing the etching conditions using two or more parameters in this manner, the V-shaped etching becomes possible. As described above, it is considered that the flow rate (concentration) of the etching gas and the flow velocity of the etching gas can also function as parameters. Therefore, by combining two or more of these parameters, it is possible to effectively obtain the V-shaped sectional shape by etching. Furthermore, by forming the V-shaped sectional shape by etching, even in the case of filling a recessed pattern whose width of the central portion is wider than that of the upper portion in the depth direction, it is possible to perform the filling film formation without generating a void by expanding the opening of the upper portion of the recessed pattern via V-shaped etching.

In the present embodiment, there has been described an example in which the rotation speed of the rotary table 2 is set as one parameter using a rotary table type substrate processing apparatus. Herein, if the rotation speed is high, it means that the contact time between the wafer W and the etching gas is set to be short, and if the rotation speed is low, it means that the contact time between the wafer W and the etching gas is set to be long. Therefore, instead of the rotary table type substrate processing apparatus, in the case of a vertical type heat treatment apparatus which loads wafers W on a wafer support (wafer boat) that can stack a plurality of wafers W at predetermined intervals in the vertical direction and which performs substrate processing such as film formation by switching the kind of a gas supplied into a vertically elongated process container while heating the process container with the wafers W put thereinto, it is possible to obtain the same effect as changing the setting of the rotation speed of present embodiment by changing the setting of the supply time period of the etching gas. Furthermore, also in the case of an apparatus that loads one wafer W on a susceptor (rotary table) and performs substrate processing such as film formation by switching a supplied gas, it is possible to obtain the same effect as changing the setting of the rotation speed of present embodiment by changing the setting of the supply time period of the etching gas. The setting of the internal pressure of the vacuum container 1 may be similarly applied to the internal pressure of the process container of each apparatus. Thus, the etching method and the method of filling a recessed pattern according to the present embodiment may also be applied to apparatuses other than the rotary table type ALD apparatus.

### EXAMPLE

Next, an example in which the present disclosure is carried out will be described.

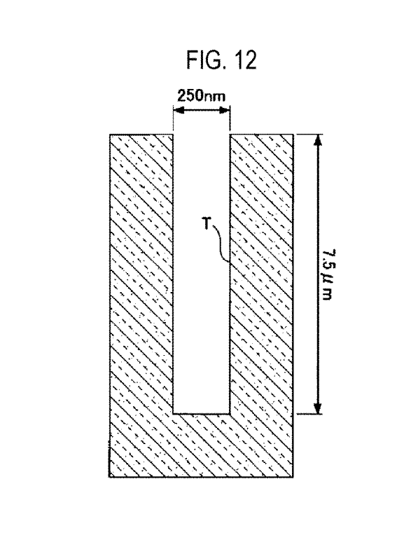

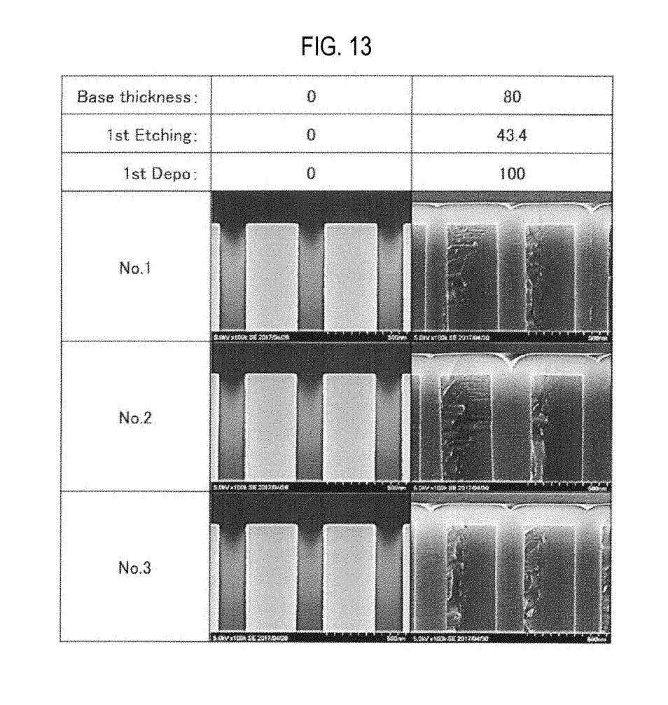

FIG. 12 is a view illustrating a shape of a trench T of a sample used in this example. As illustrated in FIG. 12, a trench T having a width of 250 nm and a depth of 7.5 μm was used as the sample.

As the film forming conditions of the example, in the first and second film forming processes, the pressure of the vacuum container 1 was set to 6.7 Torr and the rotation speed of the rotary table 2 was set to 120 rpm. TDMAS as a raw material gas was set at a flow rate of 300 sccm, and N₂ was set at a flow rate of 800 sccm and supplied as a carrier gas from the first film-forming gas nozzle 31. Furthermore, O₂/O₃ was supplied at a flow rate of 6,000 sccm.

As the etching conditions, the pressure of the vacuum container 1 was set to 5 Torr, the rotation speed of the rotary table 2 was set to 180 rpm, and ClF₃ was supplied as an etching gas from the etching gas nozzle 33 at a flow rate of 100 sccm.

Under such conditions, as described with reference to FIGS. 7A to 7D, a series of processes of filling film formation were performed in the order of the first film forming process, the etching process, and the second film forming process.

FIG. 13 is a diagram illustrating results of implementation of present embodiment. As illustrated in FIG. 13, in all the samples of Nos. 1 to 3, it was possible to obtain good results by filling a trench without a void.

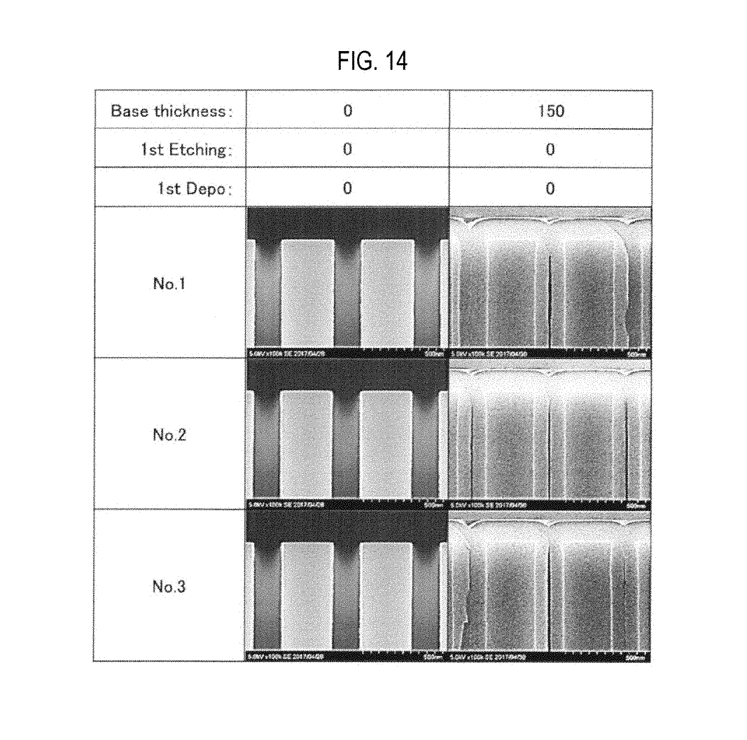

FIG. 14 is a diagram illustrating results of implementation according to a comparative example. In the comparative example, only the first and second film forming processes were performed without performing the etching process. As illustrated in FIG. 14, in all the samples of Nos. 1 to 3, sufficient filling cannot be performed due to generation of a void. In the ALD film formation which has a good coverage, the trench shape cannot be modified in the recessed pattern having a shape whose width of the central portion in the depth direction is wider than that of the upper portion as illustrated in FIG. 7A, thereby generating a void. In this respect, according to the etching method and the method of filling a recessed pattern of this example, the sectional shape of a film is formed in a V shape by performing the V-shaped etching and the final filling process is then performed, thereby enabling a filling process while reliably preventing generation of a void.

According to the present disclosure in some embodiments, it is possible to control an amount of etching in a depth direction of a recessed pattern.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method for etching a film in a recessed pattern formed on a surface of a substrate in a process chamber to form a V-shaped sectional shape, comprising:
setting two or more parameters of the process chamber to such conditions that an etching rate of the surface of the substrate becomes higher than that of an inside of the recessed pattern; and
supplying an etching gas to the surface of the substrate under the condition.

2. The method of claim 1, wherein the conditions includes a condition for reducing a mean free path of the etching gas in the process chamber by setting an internal pressure of the process chamber to become equal to or higher than a predetermined pressure.

3. The method of claim 2, wherein the conditions further includes a condition that a contact time between the etching gas and the substrate is set equal to or shorter than a predetermined time period.

4. The method of claim 3, wherein a rotary table configured to support the substrate along a circumferential direction is installed in the process chamber,
an etching gas supply region where the etching gas can be supplied to the surface of the substrate is provided in a partial region along the circumferential direction of the rotary table, and
a time period during which the substrate passes through the etching gas supply region is set equal to or less than the predetermined time period by rotating the rotary table at a predetermined rotation speed or more.

5. The method of claim 4, wherein the predetermined pressure is set within a range of 1 to 20 Torr or less, and the predetermined rotation speed is set within a range of 60 to 700 rpm.

6. The method of claim 1, wherein the etching gas is a halogen-based gas.

7. The method of claim 1, wherein the etching gas is activated to be supplied.

8. The method of claim 1, wherein the recessed pattern has a shape whose width of a central portion in a depth direction is wider than those of a bottom portion and an upper portion.

9. The method of claim 1, wherein the film is a silicon oxide film.

10. A method of filling a recessed pattern, comprising:
forming a conformal film that conforms to a shape of the recessed pattern in the recessed pattern formed on a surface of a substrate in a process chamber;
etching the conformal film to form a V-shaped sectional shape by performing the etching method of claim 1 in the process chamber; and
forming a conformal film that conforms to the V-shaped sectional shape on the conformal film having the V-shaped sectional shape in the process chamber.

11. The method of claim 10, wherein the step of forming the conformal film that conforms to the V-shaped sectional shape is performed until the recessed pattern is completely filled.

12. The method of claim 10, wherein the step of etching the conformal film to form the V-shaped sectional shape and the step of forming the conformal film that conforms to the V-shaped sectional shape are repeated twice or more.

13. The method of claim 10, wherein the conformal film is a silicon oxide film.
